(19) United States
(12) Patent Application Publication
(10) Pub. No.: US 2009/0298193 A1
(43) Pub. Date: Dec. 3, 2009

(54) ATOMIC EMISSION SPECTROSCOPY ON A CHIP

(75) Inventors: Hong Koo Kim, Pittsburgh, PA (US); Sung Jun Yoon, Pittsburgh, PA (US)

Correspondence Address: FOLEY AND LARDNER LLP;SUITE 500, 3000 K STREET NW, WASHINGTON, DC, 20007, US

(73) Assignee: UNIVERSITY OF PITTSBURGH- -OF THE COMMONWEALTH SYSTEM OF HIGHER EDUCATION

(21) Appl. No.: 12/433,448

(22) Filed: Apr. 30, 2009

Related U.S. Application Data
(60) Provisional application No. 61/071,478, filed on Apr. 30, 2008.

(51) Int. Cl. G01N 21/76; B01J 19/00; G01N 21/75; H01L 31/00

(52) U.S. Cl. 436/172; 204/164; 422/82.05; 257/429; 257/431; 257/E31.001

(57) ABSTRACT

A method of inducing explosive atomization of materials is provided using a metal-oxide-semiconductor (MOS)-based structure under electrical excitation. Explosive atomization of the gate electrode and surrounding dielectric materials creates a microplasma that is substantially confined with the device at the metal/dielectric interface. The device can generate a microplasma in either the accumulation or inversion regime. The high degree of confinement of the microplasma allows chip-scale implementation of atomic emission spectroscopy and detection using a minimal amount of analyte.

### CROSS-REFERENCE TO RELATED PATENT APPLICATIONS

This application claims priority from Provisional Application U.S. Application Ser. No. 61/071,478 filed Apr. 30, 2008, incorporated herein by reference in its entirety.

### STATEMENT REGARDING FEDERALLY-SPONSORED RESEARCH OR DEVELOPMENT

This invention was made with Government support under Grant numbers NIRT-0403865 and ECS 0424210 awarded by the National Science Foundation. The Government has certain rights in the invention.

### BACKGROUND OF THE INVENTION

The present invention relates generally to the field of plasmas and more specifically to microplasmas generated by Coulomb fragmentation within a metal-oxide-semiconductor (MOS) structure, or a metal-insulator-metal (MIM) capacitor structure.

Coulomb fragmentation is usually triggered by sudden ionization with high-intensity (≧10¹⁴ W/cm²) femto-second laser pulses. At this intensity level, the laser field exceeds the Coulombic field strength seen by an electron in the core states of an atom. The valence/core electrons are quickly ripped off and the ionized metal clusters fragment before thermalization occurs.

Methods of atomization being used for elemental analysis can be categorized into thermal (flames and electrothermal), electrical (cathodic arc/glow discharge), or optical (laser-induced breakdown). In these conventional atomization/excitation methods, only a small fraction of the atoms is in an excited state, and in thermal excitation case this fraction is highly temperature dependent. In the case of plasmas, the intensities of emission lines in a spectroscopic light source strongly depend on the choice of carrier gas and discharge mode, mainly attributed to collisional energy transfer with carrier-gas atoms. Whether it is a micro or macroscale plasma, the plasma is usually formed in a gas or liquid phase.

For example, a commonly employed method for elemental analysis is inductively-coupled-plasma atomic emission spectrometry (ICP-AES). In ICP-AES, a sample in a solution phase is nebulized, resulting in a fine spray or aerosol in a flowing carrier gas. The aerosol is introduced into a plasma torch. A high voltage spark is applied to ignite a plasma flame, which is then maintained through induction heating of the gas by an RF radiation. The temperature of the plasma is typically 7000-8000 K, and molecules contained in the aerosol sample are atomized. The majority of the atoms are also singly ionized and many of the ions are produced in various excited electronic states. The radiation emitted from these excited ions is then analyzed by a spectrometer. Despite its wide applicability, the conventional ICP is anchored to a laboratory instrument. This is mainly due to the size, weight and gas consumption involved with the ICP operation. Another shortcoming of conventional ICP-AES is that certain prominent nonmetal (e.g., C, N, O, H) are not analyzed.

In an alternative example, Z. Vager et al., “Coulomb explosion imaging of small molecules,” Science 244, 426-431 (1989), disclose a method of generating Coulomb explosion using highly kinetic ions (˜MeV) impinged upon metal clusters, thereby inducing ionization of metal atoms.

### SUMMARY OF THE INVENTION

An embodiment of the invention provides a method of inducing explosive atomization of materials by electrical excitation. The method includes: (A) providing a structure comprising a dielectric layer disposed between a first electrode and a second electrode; and (B) applying at least one voltage pulse across the first electrode and the second electrode so as to cause Coulomb fragmentation of atoms of at least the first electrode. The Coulomb fragmentation constitutes a microplasma that is substantially localized within the structure.

Another embodiment provides a sensor for detecting an analyte via explosive atomization of materials. The sensor includes a structure that includes a dielectric layer disposed between a first electrode and a second electrode; an analyte located within or adjacent to the first electrode; a voltage source for providing at least one voltage pulse across the first electrode and the second electrode in order to cause Coulomb fragmentation of atoms of at least the first electrode, wherein the Coulomb fragmentation constitutes a microplasma that is substantially localized within the structure; and a detector for detecting photons, electrons or ions emitted from the analyte.

Another embodiment provides a device, including a first electrode comprising at least a first layer of metal having a low impact ionization energy, a second electrode, and a dielectric layer disposed between a first electrode and a second electrode, the dielectric layer having a thickness less than about 10 nm. The metal of which the first layer is composed preferably is selected from Ag, In, Sn, Zn, Ga, Cu, and a combination of these. The first layer is about 5 to 50 nm in thickness.

### BRIEF DESCRIPTION OF THE DRAWINGS

FIG. 1A is a schematic cross-sectional view of a MOS structure according to an embodiment of the invention. Electrical pulses can be applied across the metal gate and the substrate-side Ohmic contact. FIG. 1B is a schematic energy band diagram of the MOS structure depicted in FIG. 1A with a positive voltage pulse applied to the gate. FIG. 1C shows two atomic emission spectra generated by a non-limiting example of the MOS structure (15 nm Ag/8 nm SiO₂/p-type Si) operating under pulsed drive (100 V, 10 ms). Atomic lines from Ag I, Si I, Si II and O I are identified. The inset shows 10× magnification of the intensity for the spectral range of 550-1000 nm. FIG. 1C (left) shows a portion of the spectrum corresponding to the UV range (200-400 nm). FIG. 1C (right) shows a portion of the spectrum corresponding to the Vis-NIR range (400-1000 nm). FIG. 1D illustrates an energy level diagram of the neutral Ag atom, showing possible radiative transitions: 6s ²S_{1/2}-5p ²P_{3/2}; 5d ²D_{5/2}-5p ²P_{3/2}; 5p ²P_{3/2}-5s ²S_{1/2}; 6s ²S_{1/2}-5p ²P_{1/2}; 5d ²D_{3/2}-5p ²P_{1/2}; 5p ²P_{1/2}-5s ²S_{1/2}. FIG. 1E shows a luminescence image (dots) superposed on top of an electrode morphology image of the Si MOS structure. The luminescence image was captured during the first explosion of a Ag electrode, and the morphology image was taken after the explosion (scale bar, 100 μm). FIG. 1F (left) is a photomicrograph image taken over 8 pulsed drives (60 V, 10 μs) with a charge-coupled device (CCD) camera (scale bar, 100 μm). FIG. 1F (right) is a magnified view (scale bar, 5 μm) of a randomly selected area of the image shown in FIG. 1F left.

FIGS. 2A-2D are temporal profiles of current (I: top trace) and luminescence intensity (L: bottom trace) of MOS structures versus time. Single voltage pulses (+100 V amplitude, 10 ms pulse width) were repeatedly applied to the gate of the MOS structures. In FIGS. 2A-2C, the semiconductor used in the MOS structure was p-type Si. In FIG. 2D, the semiconductor was n-type Si.

FIG. 3A is an evolution of I-V characteristic of a non-limiting example of the MOS structure (10-nm Pt/15 nm Ag/8 nm SiO₂/p-type Si substrate, electrode: 0.7 mm diameter) over repeated application of a voltage pulse (100 V amplitude, 10 ms pulse width), measured before pulsed drive (“Fresh”), after the first drive (“One pulse”), after the second drive (“Two pulses”), after the fifth drive (“Three pulses”), after the tenth drive (“Five pulses”), and after the twentieth drive (“Ten pulses”). FIG. 3B shows an estimated carrier transport through localized leakage channels formed in the oxide layer of the Si MOS structure. A log-log scale plot of the I-V curve was measured after ten pulsed drives (100 V, 10 ms). In this non-limiting example, an electrode having an area of 0.35 mm×0.35 mm square was used in order to stay within the instrument current limit (20 mA at 100 V) during I-V measurement. The V^{3/2} dependence of current at above 3 V indicates a space-charge-limited current, suggesting electron transport through void channels may be formed in the oxide.

FIG. 4 shows an atomic emission spectrum generated by the MOS structure operating in the accumulation regime with a pulse amplitude of −100 V. The semiconductor in the MOS structure was p-type Si.

FIG. 5 shows an atomic emission spectrum generated by the MOS structure containing an analyte layer of soda-lime glass. Negative voltage pulses were applied to the MOS structure formed on p-type Si.

FIG. 6 shows luminescence spectrum of another non-limiting example. In this non-limiting example, a water droplet (0.2 μl) was placed on top of an Ag electrode (0.73 mm diameter) and an electrical probe touched directly the Ag electrode for pulsed drive. The luminescence spectrum was measured over 10 pulsed drives (100 V, 1 ms). A hydrogen atomic line (H I) at 656 nm is observed along with the Ag I lines.

FIG. 7A shows a micrograph of a Si MOS structure (20 nm Pt/15 nm Ag/10 nm SiO₂/p-type Si substrate) with a partially-overlapping Pt/Ag electrode. In this non-limiting example, a 20-nm-thick Pt electrode (0.73 mm diameter) was deposited on top of a 15-nm-thick Ag electrode (0.73 mm diameter) with partial overlap. FIG. 7B is a luminescence image captured over 8 pulsed drives (100 V, 10 ms). FIG. 7C shows surface morphology of the electrodes after the pulse drives.

### DETAILED DESCRIPTION OF THE PREFERRED EMBODIMENTS

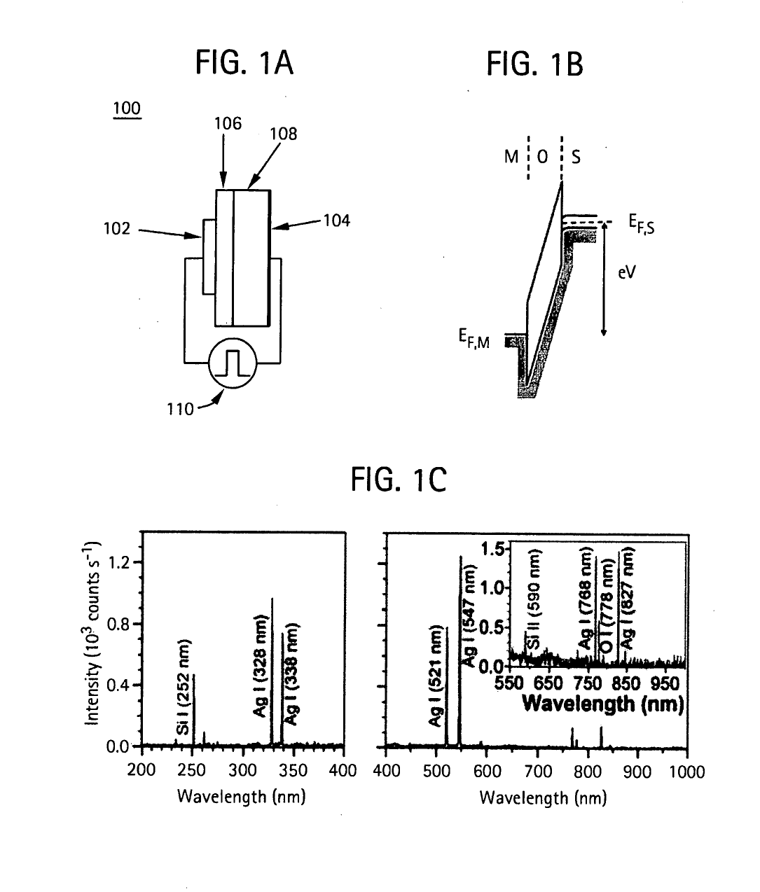

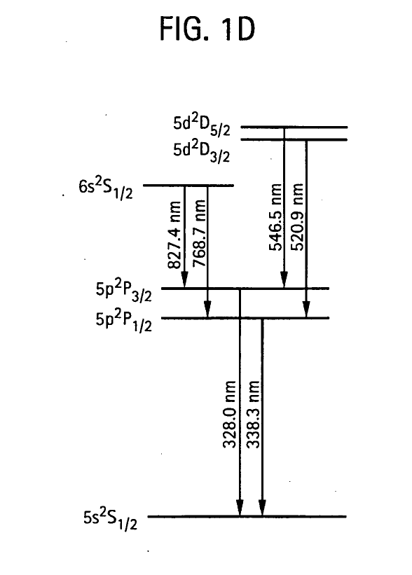

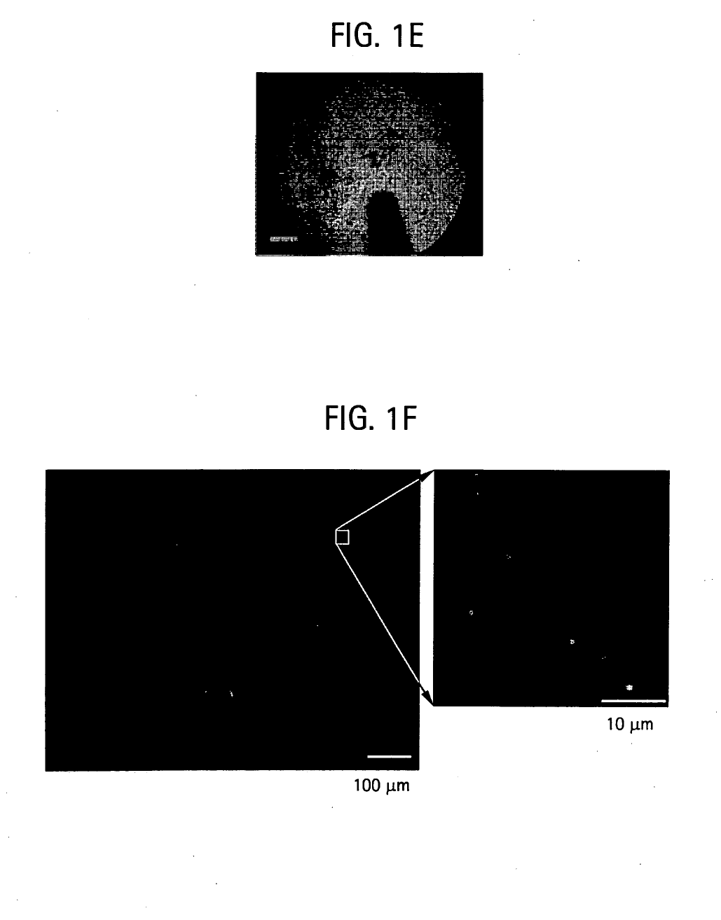

FIG. 1A illustrates a device 100 according to a first embodiment of the invention. The device 100 contains a first or top electrode 102, and a second or bottom electrode 104, and a dielectric layer 106 located between the first and second electrodes. The thickness of the first electrode 102 is less than about 100 nm, such as about 1 nm to about 30 nm. The thickness of the dielectric layer 106 in a direction from the first electrode 102 to the second electrode 104 is less than about 50 nm, such as about 1 nm to about 20 nm, more preferably less than about 10 nm. The device 100 may also include a semiconductor layer 108 that may be intrinsically doped, or can be doped to be p-type or n-type. Optionally, the semiconductor layer 108 can be omitted, in which case the device 100 comprises a MIM capacitor structure. A voltage source 110 may be electrically connected to the first and second electrodes 102, 104 in order to apply a voltage pulse to the first and second electrode.

The dielectric layer 106 is preferably a solid, such as an oxide, but it can be a gap (of vacuum, air or gas) or a liquid layer. The dielectric constant can be about 1 to about 10, such as about 3 to about 8. A metal-oxide semiconductor (MOS) structures with thick oxides (≧100 nm) is not preferable for solid-state plasma generation with analyte materials via high-energy carrier injection, due to the formation of major defects, such as craters with 10-100 μm diameters at random local spots. This dielectric breakdown behavior has been reported by N. Klein and E. Burstein, “Electrical pulse breakdown of silicon oxide films,” J. Appl. Phys. 40, 2728-40 (1969).

In one embodiment of the invention, an oxide of silicon is used. Specifically, a thermally-grown silicon dioxide (dielectric constant 3.9) layer is used as the dielectric layer 106, with a thickness of about 5-10 nm. In one embodiment, the dielectric layer 106 is grown on a p-type Si wafer, which serves as the semiconductor layer 108 of the metal-oxide-semiconductor (MOS) device 100. Other semiconductors besides Si can be used, including Ge, GaAs, GaN, GaP, InP, InAs, AlN, ZnO, or CdS. A MOS structure offers the options of controlled injection of either minority or majority carriers for plasma generation, depending on the conduction type of the semiconductor 108 and the voltage bias applied to the gate electrode 102.

The first and second electrodes 102, 104 can be made of any suitable material that is electrically conductive. For example, the material can be any metal, such as Al, Ta, Cr, Mo, W, Ni, Pd, Pt, Cu, Ag, Au, Zn, Cd, or combinations thereof. In a preferred embodiment, the first electrode is comprised of a metal characterized by a low impact-ionization energy. See W. Lotz, “Electron-impact ionization cross-sections for atoms up to Z=108,” Z. Physik 232, 101-07 (1970). Such a “low-impact-ionization-energy metal,” as that phrase is used here, is a metal, such as Ag, In, Sn, Zn, Ga, and Cu, that has a relatively low impact-ionization energy. Without committing to a particular theory or mechanism, the inventors believe that the first step in explosive atomization of analytes, placed adjacent to a first electrode, is to induce electron impact ionization of the first electrode material, leading to a Coulomb explosion of the metal. For operation at a reduced voltage level, a low threshold energy is preferred for electron impact ionization of the electrode metal. Conversely, it will be more difficult to achieve Coulomb explosion if a metal is employed that has a relatively high impact-ionization energy, such as Au, Pd, or Pt.

Preferably, the thickness of the first electrode is comparable to or less than the mean free path of the metal of which the first electrode is made. The mean free path of electrons in metal is known to be a function of electron energy; in Ag, for example, it ranges from 3 nm to 50 nm for electron energy of 10 eV to 2 eV. In one embodiment, the first electrode 102 comprises a low-impact-ionization-energy metal layer having a thickness of about 5-50 nm, for example 10-30 nm, such as 10-15 nm. The low-impact-ionization-energy metal may be any suitable materials, for example, Ag, In, Sn, Zn, Ga, Cu, or combination thereof.

Without wishing to be bound by any particular theory, the inventors believe that, in order to build up charges to the level that can trigger a Coulomb explosion, the ionization rate on the metal surface must be greater than the de-ionization rate. If a uniform flux of kinetic electrons impinging upon metal surface with current density J, this requirement translates into the threshold current density,

$${J}_{th} = \frac{e}{σ τ} ,$$

where e is the electron charge, σ is an ionization cross section of the metal atom, and τ is the effective lifetime (de-ionization time) of metal ions. Assuming σ=5×10⁻¹⁶ cm² (11), and τ˜1 ps, the threshold current density for Coulomb explosion is estimated to be 3×10⁸ A/cm², which appears to be an extreme requirement. The effective lifetime of metal ions is a crucial factor in estimating the threshold current density for Coulomb explosion. Detailed description of estimating the effective lifetime of metal ions can be found in Groeneveld et al., “Effect of a nonthermal electron distribution on the electron-phonon energy relaxation process in noble metals,” Phys Rev B 45: 5079-82 (1992). Specifically, in the case of laser-heated metal, thermalization of hot electrons is known to occur involving primarily two elemental processes, electron-electron and electron-phonon collisions. In the electron gas created by laser excitation, the excess energy of electrons is redistributed among themselves via electron-electron collisions, which occur on the time scale of ˜10 fs. The electron gas transfers energy to the lattice via electron-phonon collisions, reaching a thermal equilibrium in a relatively longer time frame (˜1 ps). In the case of laser-heated Ag or Au films, for example, the electron-phonon energy relaxation time is known to be 0.7-0.8 ps at 300 K (and longer relaxation times at higher temperatures). The de-ionization process of metal ions may follow the electron-phonon relaxation time frame (˜1 ps) as assumed above in the threshold level estimation.

Although no particular theory need be implicated, low energy electrons (injected or generated) in the thin metal layer of the first electrode 102 may experience potential barriers at the air-side and oxide interfaces, while the barrier heights are basically determined by metal work function and electron affinity. Accordingly, one advantage of the first electrode 102 having a thickness comparable to the mean free path is that the low energy electrons will remain confined in the potential well, whereas high energy electrons may penetrate through the metal after impact ionization. This feature of the device 100 is indeed critical for generating Coulomb fragmentation.

FIG. 1B illustrates a band diagram of the MOS structure under high electric field. A voltage pulse is applied to the first and second electrodes 102, 104 such that an electric field is created in the dielectric layer 106. The electric field has a value that is between the breakdown field of the dielectric layer (5×10⁶ V/cm for silicon dioxide) and the Coulomb electric field in a hydrogen atom (5×10⁹ V/cm). For example, for a pulse amplitude of 30-200 V across a 5-10 nm-thick silicon dioxide layer, the electric field is about 1×10⁸ V/cm. Electrons are injected into the conduction band of the gate oxide (SiO₂) layer initially via the Fowler-Nordheim tunneling process, i.e., tunneling through the potential barrier at the SiO₂/Si interface under the high electric field. The injected electrons accelerate under the strong field across the oxide layer. Considering the given oxide thickness (5-10 nm) and mean free collision path (3-4 nm) in oxide, the electrons are likely to be quasi-ballistic at least for the initial period of field application, and will gain a significant amount of kinetic energy under the high voltage drive. This will cause impact ionization of Ag atoms at the Ag/SiO₂ interface. The work function of polycrystalline Ag is 4.3 eV. When interfaced with SiO₂, the effective ionization energy of Ag may be even lower than this value. The pulse parameter can be varied. For example, the pulse width can be between about 1 μs to about 100 ms, and the voltage can be between about −50 V to about −200 V or between about +50 V to about +200 V.

Without committing to any particular theory, the inventors believe that, when the impact-ionized charges quickly build up at or near the Ag/SiO₂ interface, before being neutralized by thermal electrons, a sudden fragmentation will occur when the Coulomb energy (3.5 eV, for example, when singly-charged Ag ions are at closest-neighbor distance of 0.28 nm) exceeds the binding energy of Ag atoms in the metal (˜2.3 eV). The Ag atoms thus produced are likely to be in excited states and will subsequently relax, emitting photons that correspond to the internal radiative transitions. The fragmented metal atoms will take different relaxation paths, depending on their charge states (neutral or ion). In the case of neutral atoms, the excited Ag atoms will take an internal relaxation process with possible emission of photons. In the case of atomic ions, the Ag atoms will go through a recombination process with electrons. This ion-electron recombination process may occur either in a radiative recombination or in another process called dielectronic recombination. The former is the inverse photoionization process and is known to be efficient with relatively low energy of electrons. The latter is a resonant process, in which an incoming electron excites an electron of the ion for the amount of energy gained by capturing the incident electron. The state in which the incident and second electrons are both in excited orbitals of neutral Ag atom is not stable, and can undergo a transition to a stable state of the neutral atom, emitting photons.

The dielectronic recombination phenomenon described above has been observed in high-temperature plasmas, upper atmosphere, and distant stars, as reported by H. S. W. Massey and D. R. Bates, “The properties of neutral and ionized atomic oxygen and their influence on the upper atmosphere,” Rep. Prog. Phys. 9, 62-74 (1942) and W. G. Graham et al., Recombination of Atomic Ions, NATO ASI Series B: Phys. Vol 296 (Plenum, New York, 1992). Unlike those plasmas, however, the Coulomb fragmentation of the present embodiment constitutes a microplasma that is substantially localized within the device 100, such as at the solid interface between the Ag gate electrode 102 and the dielectric layer 106.

As a non-limiting example, a silver electrode (10-15 nm thickness; 0.73 mm diameter) was prepared on top of a thin SiO₂ layer (5-10 nm thickness) thermally grown on a p-type Si substrate. Positive voltage pulses (30-100 V amplitude and 0.01-10 ms width) were applied to the gate, driving the MOS to form an inversion channel in the Si substrate as illustrated in FIG. 1B. The pulse amplitude was set such that the electric field in the gate oxide (˜1×10⁸ V/cm) is to be significantly higher than the oxide breakdown field strength (10⁷ V/cm).

FIG. 1C shows the luminescence spectra resulting from the explosion measured with +100 V pulses applied to the gate. The pulse width was varied in the range of 1 μs to 10 ms. A CCD-based spectrometer (B&W Tek model BRC-111A-UV for spectral range of 200-400 nm and BRC-111A-UV/Vis for 350-1050 nm) was used in detecting and resolving the luminescence spectra. In the spectrum on the left, FIG. 1C shows the spectrum for wavelengths corresponding to the UV range (200-400 nm). In the spectrum on the right, FIG. 1C shows the spectrum for wavelengths corresponding to the Vis-NIR range (400-1000 nm). The UV range spectrum shows several atomic lines, with the 328 nm and 338 nm lines as major ones, and the 252 nm line as a minor one. The two major lines at 328 and 338 nm correspond to the 5p ²P_{3/2}-5s ²S_{1/2} and 5p ²P₁₋₂-5s ²S_{1/2} transitions of the neutral Ag atom, respectively. An atomic line of Si is also observed at 252 nm. The Vis-NIR range spectrum reveals the 521 nm (5d ²D_{3/2}-5p ²P_{1/2}), 547 nm (5d ²D_{5/2}-5p ²P_{3/2}), 769 nm (6s ²S_{1/2}-5p ²P_{1/2}), and 827 nm (6s ²S_{1/2}-5p ²P_{3/2}) lines, all corresponding to the major transitions of the neutral Ag atom.

It is believed that minority carrier injection is involved to initiate atomization of metal at the gate/dielectric interface, and the excited Ag atoms relax through a cascade of transitions, following the energy level scheme shown in FIG. 1D. Atomic luminescence from silicon (Si I at 252 nm and Si II at 590 nm) and neural oxygen (O I at 778 nm) is also observed, indicating adjacent dielectric is also atomized. Specifically, the work function of polycrystalline Ag is 4.3 eV, and when interfaced with SiO₂, the effective ionization energy of Ag may be even lower than this value. As charges build up via impact ionization, the Coulomb energy grows. A sudden fragmentation occurs when the Coulomb energy (3.5 eV, for example, when singly-charged Ag ions are at closest-neighbor distance of 0.28 nm) exceeds the binding energy of Ag atoms in the metal (˜2.3 eV). The Ag atoms thus produced are likely to be in excited states and subsequently relax, emitting photons that correspond to the internal radiative transitions. In the case of atomic ions, the Ag atoms go through a recombination process with electrons. This ion-electron recombination process may occur either in a radiative recombination or in another process called dielectronic recombination. The latter is a resonant process, in which the energy gained by capturing an incoming electron is used to excite an electron of the atom to a higher energy level. This neutralized atom subsequently relaxes emitting a photon.

FIG. 1E shows a luminescence image (dots) superposed on top of an electrode morphology image of the Si MOS structure. The luminescence image was captured during the first explosion of a Ag electrode, and the morphology image was taken after the explosion. (scale bar, 100 μm). This close comparison of the luminescence image with the electrode morphology reveals that the explosion occurred at discrete local spots, and each spot incurred an eruption and fragmentation of Ag metal from the surrounding area. The average spacing between the explosion sites is estimated to be ˜5 μm. Without wishing to be bound to any particular theory, the inventors believe that this highly localized explosion of Ag indicates involvement of discrete leakage channels formed in the oxide, which allows injection of kinetic electrons for impact ionization. The distribution of luminescence spots shows a strong correlation with the explosion sites but spreads more broadly. Thus, some of the fragmented Ag apparently emitted photons during the flight away from the eruption sites.

FIG. 1F shows atomic luminescence from the MOS structure that was imaged with a CCD camera while under pulsed excitation. The overall color of emission is green, while intense purple emission is observed in the vicinity of the probe. The luminescence image taken over repeated drives (10 explosions) shows a globally uniform distribution of luminescence green dotes (FIG. 1F, left). The green luminescence corresponds to the atomic lines in the visible range (521 nm and 547 nm), and the purple luminescence is attributed to the UV lines at 328 nm and 338 nm. The change of emission wavelength across the electrode area (from green to purple towards the probe region) indicates a change in the relaxation dynamics of Ag atoms, e.g., from the ²P-²S transitions to the ²D-²P transitions, which can be explained by a shift of energy distribution of kinetic electrons injected onto the metal surface. After repeated occurrence of Coulomb explosion, the connectivity of the Ag electrode deteriorates, as confirmed by a sheet resistance measurement performed afterward. The finite conductance of the Ag electrode causes a potential drop across the electrode area itself The actual amount of voltage applied across the gate oxide layer is then significantly lower in the region farther away from the probe point. A higher voltage across the gate oxide would result in higher kinetic energy of impinging electrons and a larger electron flux, thus providing a different ambient for excitation/relaxation of Ag atoms. The homogeneous nature of the Ag atomic luminescence indicates that Coulomb explosion occurred with a relatively uniform distribution across the electrode.

In the inset in FIG. 1F (FIG. 1F, right), a magnified view of the CCD image of the green luminescence reveals that the luminescence centers (green or purple dots) are uniformly distributed at a microscopic level with average distance of ˜10 μm (i.e., with an areal density of ˜1×10⁶ cm⁻²). This magnified view of the luminescence image reveals that each luminescence spot (green or purple dots) is on the single pixel level, implying that its physical size is below the resolution limit of imaging (<0.5 μm). It is believed that highly localized but uniformly distributed injection channels of kinetic electrons across the electrode area are involved, in contrast to the earlier reports on the breakdown behavior tested with Si MOS capacitors that have an oxide layer thicknesses of 20-100 nm, such as those reported by N. Klein and E. Burstein, “Electrical pulse breakdown of silicon oxide films,” J. Appl. Phys. 40, 2728-2740 (1969).

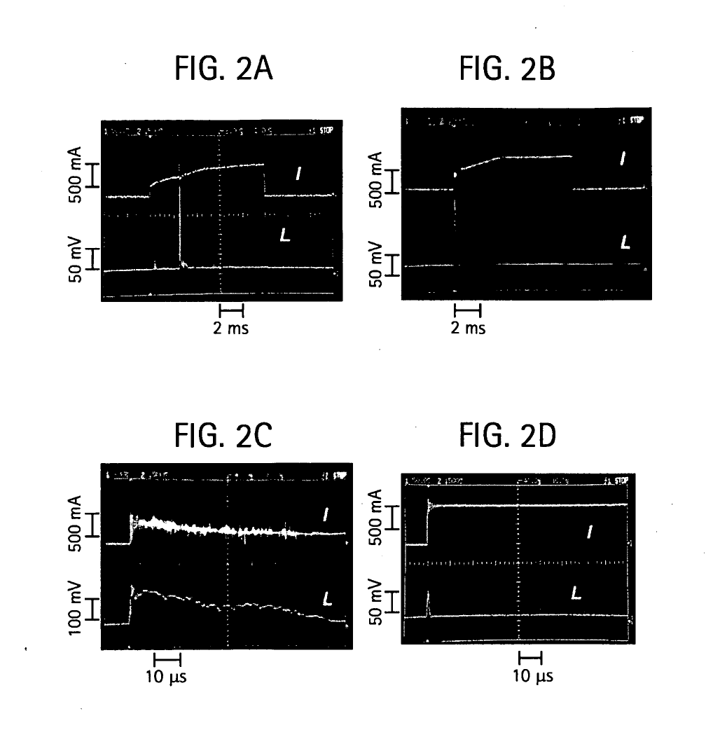

FIGS. 2A-2D show the time dependence of injection current and luminescence under a pulsed voltage drive. Single voltage pulses (+100 V amplitude and 10 ms pulse duration) were repeatedly applied to the gate with an interval>60 s, and the current and luminescence transients were recorded during each drive.

FIG. 2A shows the first luminescence transient observed during the fifth pulse. The measured luminescence intensity corresponds to the integral power captured over the visible-to-NIR range of spectrum of Ag atomic luminescence. For the first 2.5 ms duration, no luminescence was detected, and then a burst of emission suddenly appeared, which lasted for ˜100 μs. No luminescence was observed during the first four pulses, although the injection current remained at a nearly constant level at ˜1 A during the entire duration of pulse. The charge injection time counted up until the onset of luminescence was ˜40 ms. From the injection level (800 mA) and duration (40 ms), the total amount of charges injected into the oxide was estimated to be 0.032 C, or 8 C/cm² when normalized with the electrode area (3.9 ×10⁻³ cm² diameter). This well matches the charge-to-breakdown values reported in literature for a Si MOS structure with similar oxide thickness (1-100 C/cm² at 10 nm), such as those reported by I. C. Chen, S. Holland, K. K. Young, C. Chang, and C. Hu, “Substrate hole current and oxide breakdown,” Appl. Phys. Lett. 49, 669 (1986) and D. J. DiMaria, E. Cartier, and D. Arnold, “Impact ionization, trap creation, degradation, and breakdown in silicon dioxide films on silicon,” J. Appl. Phys. 73, 3367-3384 (1993). This transient measurement result clearly suggests that the burst of emission occurred with oxide breakdown. A large amount of kinetic electrons injected through the oxide are then believed to have caused atomization of Ag and thus atomic luminescence.

FIG. 2B shows the first luminescence transient observed during the sixth pulse. FIG. 2B shows that, once an initial breakdown has occurred, kinetic electrons can be readily injected. From the fourth pulse or after, the luminescence appeared in synchronization with the leading edge of the voltage/current pulse. A close look at the transient profile reveals numerous, persistently occurring current spikes during the luminescence. The charge injection time counted up until the first luminescence burst is ˜50 ms. From the injection level (800 mA) and duration (50 ms), the total amount of charges injected into the oxide is estimated to be 0.04 C, or 10 C/cm² when normalized with the electrode area (4×10⁻³ cm²). Without wishing to be bound to any particular theory, the inventors believe that this result well matches the charge-to-breakdown values reported in literature for a Si MOS structure with similar oxide thickness (1-100 C/cm² at 10 nm). From the sixth pulse or after, luminescence occurred in synchronization with the rising edge of the voltage/current pulse. A close look at the transient profile reveals numerous, persistently occurring current spikes during the luminescence.

FIG. 2C was measured during the seventh drive (the second luminescence burst). It shows that many fine features are observed in the luminescence transient and that the overall luminescence intensity monotonically decays. This suggests a multitude of small localized explosions, instead of a single global explosion, during the luminescence period (˜100 μs) and is consistent with the electrode morphology shown in FIG. 1E. Although a particular theory need not be implicated, it is believed that, as the electrode material at each explosion site is depleted by eruption, the luminescence becomes extinct prior to the end of the drive. With each drive, explosions occur at different, new locations, with decreasing luminescence intensity and duration over repeated drive. Notably, the overall injection current remains high during the drive, and this suggests that the leakage channels continue to conduct for the remaining pulse duration. This implies a continuous deposition of energy into the system even after the extinction of luminescence. The inventors understand that these “mini-explosions” might be associated with the microscopic structures intrinsic to the metal electrode, i.e., granular structures of a Ag layer. The size of the individual explosion seed site may be on the same scale with the grain/crystallite sizes (˜10 nm) of the film. This estimate is consistent with the discussion made with regard to FIG. 1F above. It is believed that nanoscale, localized leakage channels may be formed in oxide, through which kinetic electrons are injected and impact-ionize individual metal nanostructures.

FIG. 2D was obtained using a MOS structure formed on an n-type Si. Voltage pulses (+100 V, 10 ms) were applied to the gate. The luminescence lasted only for ˜1 μs, about two orders of magnitude shorter than the p-type substrate case. Without committing to any particular theory, it is believed that abundant electrons that are dumped into the gate/oxide interface tend to reduce the relaxation time. In turn, this will quickly neutralize the metal ions being formed via impact ionization. It should be noted here that the current flow remains at a constant level throughout the pulse duration. This implies a continuous deposition of energy into the system. The temperature is then expected to rise monotonically during the pulse, which may lead to melting of the electrode metal. Optical microscopy inspection after each drive with various different pulse width reveals that the electrode surface morphology has evolved through at least two distinct stages. Initially, tiny crater-like features were formed the explosion, followed by major macroscale deformation that looks to be caused by melting during the post-explosion period of the pulse. This luminescence and morphology characteristics supports the theory that Coulomb explosion is the prime mechanism of the atomic luminescence observed above.

As explained above, the time scale of a Coulomb explosion event (impact ionization to fragmentation) may be on the same order as the effective lifetime of metal ions (˜1 ps). In the above described non-limiting examples, pulses having a much longer pulse width (up to 10 ms) were used to initially forms nanoscale leakage channels in the oxide layer in a more definite time frame. The oxide breakdown process is known to require a certain amount of charge injection into the oxide, generally termed as the charge-to-breakdown condition: 1-100 C/cm² for 10-nm oxide thickness. This requirement translates into an injection time of ˜10 ms order for 1 A current when an around 0.7-mm-diameter electrode is used. Thus-formed nanochannels are found to serve as a conduit for ballistic transport of electrons as discussed below. These kinetic electrons are expected to induce impact ionization of metal, and possibly a Coulomb explosion when the injection current density in a nanochannel reaches the threshold level specified above. It should be noted that the nanochannels may form randomly on both temporal and spatial domains for a given pulse drive, and as such the explosive atomization and resulting luminescence events occur with a scattered distribution (e.g., as shown in FIG. 2C). Use of long pulse width will inevitably deposit a proportionally large amount of heat into the metal through the nanochannels. This would induce local melting of metal when the heat deposition reaches a sufficient level. Optical microscopy inspection after each drive with various different pulse width reveals that the electrode surface morphology has evolved through at least two distinct stages, initially, microscale eruption of Ag electrode during the explosion, followed by major macroscale deformation that appears to be caused by melting of Ag metal during the post-explosion period of the pulse.

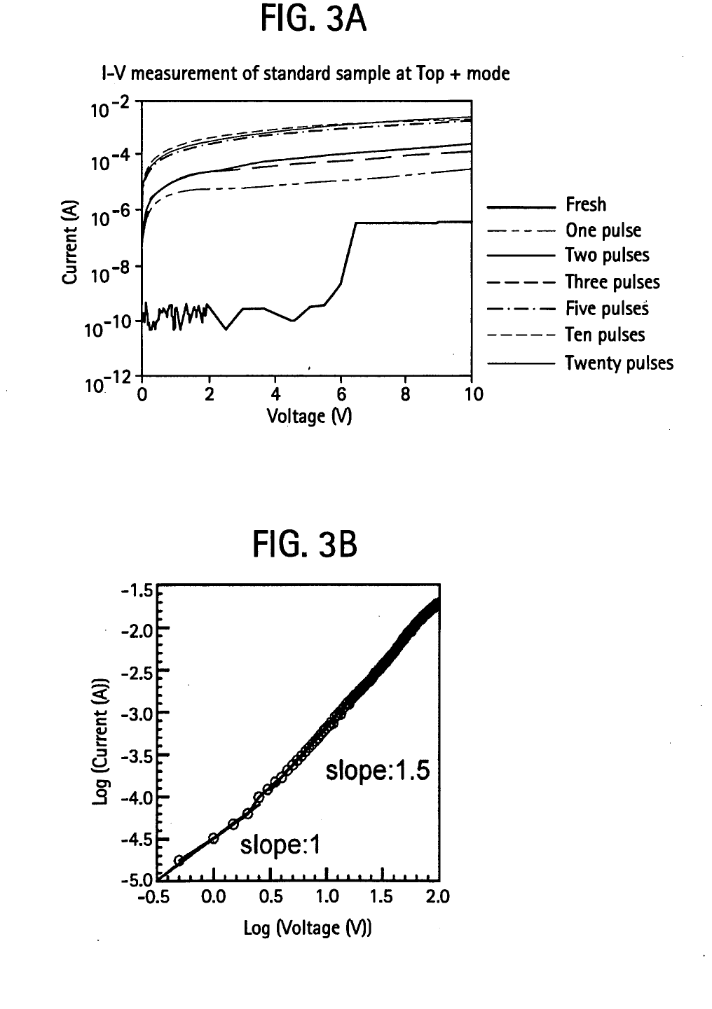

FIG. 3 shows current-voltage (I-V) curves that further confirm the role of kinetically energetic carriers with high current densities in Coulomb explosion. Preferably, ions are generated and accumulated such that an explosion threshold is reached before thermalization occurs. It is believed that for a material system with the electron impact ionization cross section, σ, and the relaxation (deionization) time, τ, the minimum level of kinetic electron injection required for Coulomb explosion can be expressed as J=e/στ, where e is the electron charge. The nonequilibrium distribution of laser-heated electrons in metal is known to be thermalized in the time scale of ˜1 ps via electron-electron scattering and electron-phonon coupling. In the case of electrical excitation like the present work, some of the injected electrons in the metal layer will transport away from the metal because, unlike the laser excited case, the probe-contact region has no surface potential barrier to confine the electrons. Some highly kinetic electrons will also escape away overcoming the potential barrier at the metal/air interface. This suggests a longer lifetime of ions compared to the optical excitation case. Assuming σ=5×10⁻¹⁶ cm² and τ≧1 ps, the upper bound of threshold injection level is then estimated to be 2×10²⁷ cm⁻²-s⁻¹, or 3×10⁸ A/cm² in terms of current density.

FIG. 3A shows the evolution of current-versus-voltage (I-V) characteristic of the MOS structure over repeated application of a pulse (100 V amplitude and 10 ms width): after each pulse drive the I-V characteristic was measured for V of 0 to 10 V. A fresh sample (before pulse drive) shows tunneling-limited current at ˜10⁻¹⁰ A, which corresponds to a nominal current density (normalized by the electrode area) of ˜10⁻⁸ A/cm². The current jumps up to the 10⁻⁵ A level after the first pulse, and then to the 10⁻⁴ A level after the second pulse, all read at 10 V. It finally settles at around the 10⁻³ A level after the fifth pulse. Without implicating a particular theory, the inventors note that this dramatic increase can be attributed to formation of localized leakage paths in the oxide. If ˜3 nm-diameter leakage channels is assumed, with an area density of 1×10⁶ cm⁻², then the measured injection current (0.5 A at 100 V: FIG. 2B) translates into a current density of ˜1×10⁹ A/cm² in the individual nanochannels. This number is sufficiently larger than the injection threshold estimated above for Coulomb explosion. A bright luminescence with explosion of the Ag electrode was observed from the sixth pulse drive (not shown). It is interesting to note the luminescence originating from Si²⁺ ions (e.g., the 590 nm line) was clearly observed whereas none from Ag²⁺ ions (data not shown). The impact ionization energies of Ag, Ag⁺, Si, and Si⁺ are 7.5 eV, 21 eV, 8.2 eV, and 16 eV, respectively. Without committing to any particular theory, inventors believe that this result suggests that the kinetic energy of injected electrons involved in the present work ranges up to over 16 eV. In the case of moderately-high field strength (10⁷ V/cm) in 5-to-10-nm-thick SiO₂, the tail of energy distribution of electrons in the oxide is known to extend up to 7-8 eV (27, 28). In the case of leakage channels formed in oxide, the ballistic nature of electron transport appears to be significantly enhanced, enabling the attainment of high kinetic energy (up to ˜16 eV) under the strong electric field (˜10⁸ V/cm). It is believed that the space-charge-limited current behavior with clear V^{3/2} dependence suggests that the leakage channels are basically void channels formed by nanoscale percolation of vacancy defects in oxide.

In order to understand the mechanisms of current transport through the oxide layer that has experienced the high voltage pulses, the I-V characteristic of a Si MOS was examined for V of 0 to 100 V, as shown in FIG. 3B. Without wishing to be bound to any particular theory, the inventors believe that the estimated I-V curve shows an Ohmic behavior in the low voltage range. For V>3 V, the slope gradually increases to 1.5. The V^{3/2} voltage-dependence is characteristic of the Child-Langmuir space-charge-limited current in a narrow gap with parallel electrodes:

$$J = \frac{4}{9} ɛ \sqrt{\frac{2 e}{{m}^{*}}} \frac{{V}^{3 / 2}}{{d}^{2}} ,$$

where ε is the permittivity of gap insulator, m* is the effective mass of electron, and d is the gap size. This Ohmic-to-space-charge-limited transition indicates that injected carrier density becomes dominant over the volume generated carrier density. This space-charge-limited current formula assumes ballistic transport of electrons across the gap with negligible barrier height for carrier injection. With the initial breakdown process (during the first four pulses), the barrier height for electron injection at the SiO₂/Si interface is believed to be significantly reduced, and this allows for injection/transport of a large amount of kinetic electrons through leakage channels. Assuming ε=4εₒ (εₒ is the free-space permittivity) and a free-space electron mass for m*, the formula produces an injection current of ˜10⁹ A/cm² at V=100 V and d=10 nm. This closely matches the channel current density estimated above based on the I-V measurement result. Overall this I-V analysis clearly confirms that the requirements of Coulomb explosion, i.e., injection of kinetic electrons with high current density, can be met in the MOS structure with the nanoscale channels formed in oxide.

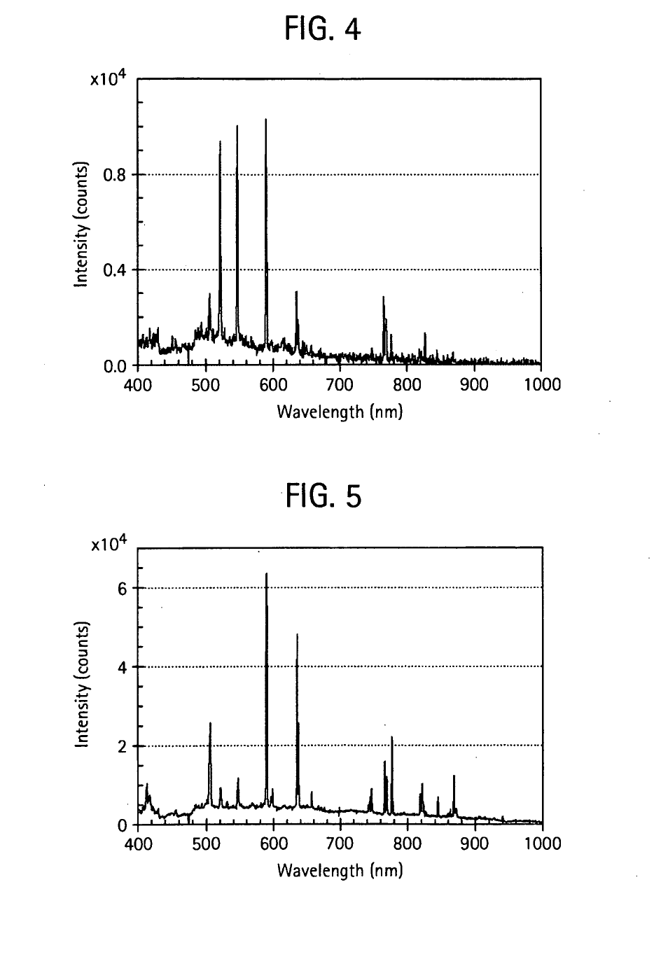

FIG. 4 shows the emission spectrum from a MOS structure made of p-Si operating in the accumulation regime (negative voltage pulse). The negative voltage pulse induces initially an emission of electrons from the gate toward the oxide, leaving metal ions on the gate/oxide interface. Similar to the case of Coulomb explosion with positive voltage drive, the ions can go through a Coulomb fragmentation process, resulting in atomic luminescence. Besides the Ag atomic lines, the Si atomic lines are also observed. This indicates that adjacent dielectric is also atomized during explosion of the Ag electrode.

Optionally, a layer of silicon nitride is deposited between the first electrode 102 and the dielectric layer 106. The silicon nitride layer is believed to minimize the oxidative reaction of Ag atoms by oxygen from the gate oxide, which degrades the Ag electrode. Such a structure (Pt/Ag/SiN/SiO2/Si) demonstrated improved lifetime throughout pulsed operation. Besides silicon nitride, other materials may be used to protect the gate electrode from oxidative damage caused by oxygen atoms reacting with the gate oxide.

The device 100 of the disclosed embodiments has wide ranging applications in elemental analysis, spectroscopy, and light sources. An advantage of the present invention is the extreme miniaturization of instrumentation and sample sized used with the device 100. For example, the device 100 can be a light-emitting display using different dopants for generating a variety of emitted colors and wavelengths. Alternatively, the device 100 can be a sensor for detecting the presence of an analyte. In the case of a sensor, an analyte is located in close proximity to the microplasma formed within the device. The analyte is at least partially atomized or ionized by the explosive fragmentation of metal electrode. For example, the analyte is directly ionized as the substance undergoing Coulomb fragmentation. Or, the analyte is indirectly ionized after the atoms in the first electrode 102 undergo Coulomb fragmentation. The presence of the analyte is detected by measuring a signature characteristic of the analyte. For example, a photodetector (such as a CCD-based spectrometer) is used to collect and detect photons emitted from the analyte. In an embodiment, an electroluminescence corresponding to the internal relaxation transitions within the analyte can be detected. Alternatively or in addition to photon detection, electrons or ions emitted from the analyte are detected using suitable detectors, such as a detector used for scanning electron microscopy. The device 100 can be located in a vacuum, in atmospheric pressure, or in a liquid.

For example, the analyte can be located within or adjacent to the first electrode 102. As in FIGS. 1-4, the analyte can be the first electrode 102 itself. In another embodiment, the analyte may be deposited on a top surface of the first electrode 102 opposite the dielectric layer 106. If a Pt layer is used, then the analyte can be deposited on top of or below the Pt layer. When the analyte is located on top of the first electrode 102, electrical contacting to the voltage source can be accomplished on portions of the first electrode 102 that are not covered by the analyte or from the side or beneath the first electrode 102. Alternatively, the analyte can be located below the first electrode 102 such that it is sandwiched between the first electrode 102 and the dielectric layer 106, or between the first electrode 102 and the silicon nitride layer if such is used. Optionally, the device may include a microfluidics system for precisely positioning the analyte at the desired position.

FIG. 5 show the emission spectrum from a MOS structure containing an analyte within the gate electrode. The analyte was a thin-layer (˜1 m thick) of Ag-containing soda-lime glass sandwiched in the gate/oxide interface to form a structure comprising: Pt/soda-lime-glass(Ag)/SiO2/Si. Negative voltage pulses were applied to the gate electrode through the Pt overlayer. The spectrum in FIG. 5 shows atomic emission lines from the constituent elements of the analyte layer: Ag, Si, O, N, and Na.

A variety of analytes can be detected, including organic or inorganic materials. Organic analytes include biological materials, such as DNA, proteins, and viruses. Inorganic analytes include semiconductors, transition metals, lanthanides and actinides. The analytes can be in the form of a powder or thin film. For example, the analyte can be a thin film with a thickness that is preferably less than about 50 nm, such as about 1-10 nm in thickness. The analyte can be deposited using a variety of deposition methods, including sputtering, spin coating, drop coating, spray coating, or a combination thereof. Alternatively, the analyte can be the electrode itself, which does not have any thickness limit.

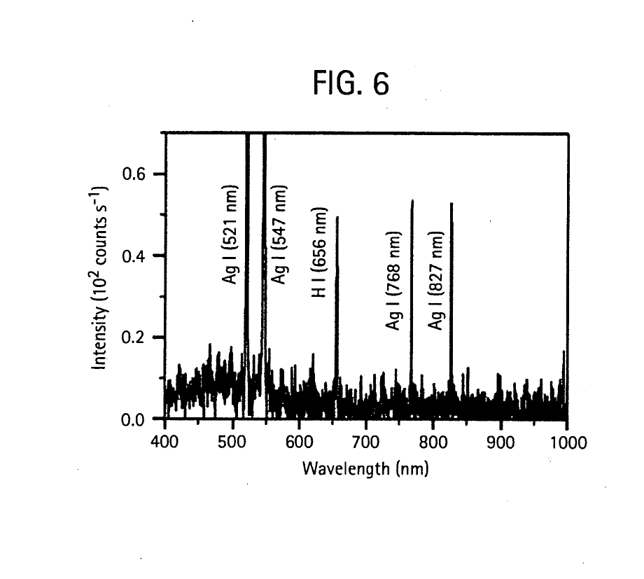

For example, in a non-limiting example, a water droplet (0.2 μl, deionized water) was placed on top of the Ag electrode (0.73 mm diameter) of a Si MOS structure (15 nm Ag/8 nm SiO₂/p-type Si). FIG. 6 shows an emission spectrum resulting from the sample under a pulsed drive. Besides the Ag atomic lines, a clear luminescence from hydrogen atoms is observed at 656 nm, which corresponds to Balmer emission (n=3→n=2). In this experiment, the hydrogen atomic line was always accompanied by the Ag atomic lines. These results are believed to indicate that the Ag atoms produced by explosive atomization fragmented water molecules, producing hydrogen atoms.

In some embodiments, the device 100 shown in FIG. 1A may further comprise an extra metal layer added on top of the metal gate 102. This additional metal layer can alter the potential well profile, and can be designed such that the dynamics of neutralization of metal ions is modified. For example, in some embodiments, a thin metal layer having work function higher than the gate metal's is added. In these embodiments, a local potential well would be formed, inducing the electrons to fall into the local step.

For example, in one embodiment, a layer of Pt may be deposited on the top surface of the Ag gate electrode 102. When a Pt layer is used, the gate electrode does not degrade as quickly as it does without the Pt layer. The result is a significant improvement in the lifetime of the device during pulsed operation. Without being bound to any particular theory, it is believed that the improved endurance of Pt is ascribed to the higher binding energy (5 eV) compared to that of Ag (3.5 eV). Higher binding energy implies higher threshold for Coulomb explosion, and an explosion will occur preferentially with Ag and not with Pt atoms. Optionally, the first electrode 102 is made entirely of Pt or any other metal having a higher binding energy than Ag.

The inventors believe that the above modification of gate electrode may keep electrons away from the metal ions formed primarily on the metal/oxide interface, therefore increase the de-ionization time, and thus reduce the threshold current density for Coulomb explosion. Without wishing to be bound to any particular theory, they understand that the electron-phonon relaxation time is a more relevant factor for the effective lifetime of metal ions than the electron-electron relaxation time, and that such a metal surface modification improves the performance of the device in achieving Coulomb explosion.

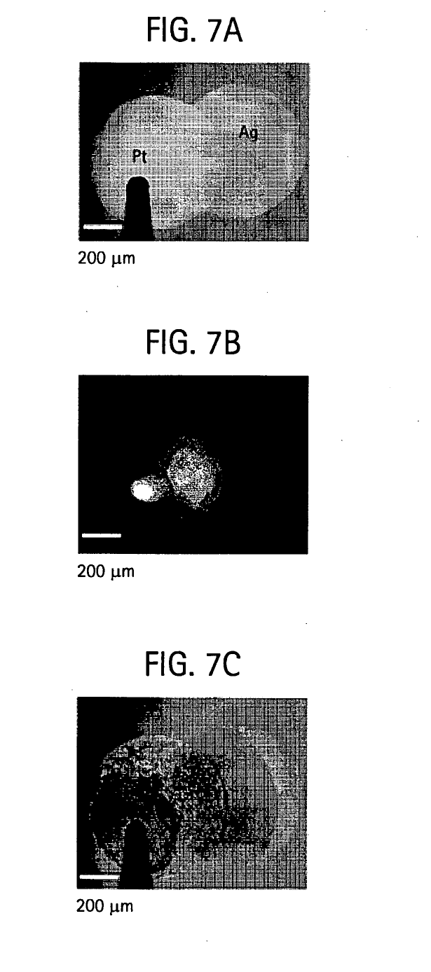

As shown in FIGS. 7A-C, the atomic luminescence was enhanced in the Pt-covered Ag area. Specifically, FIG. 7A shows a micrograph of a Si MOS structure (20 nm Pt/15 nm Ag/10 nm SiO₂/p-type Si substrate) with a partially-overlapping Pt/Ag electrode. A 20-nm-thick Pt electrode (0.73 mm diameter) was deposited on top of a 15-nm-thick Ag electrode (0.73 mm diameter) with partial overlap. FIG. 7B is a luminescence image captured over 8 pulsed drives (100 V, 10 ms). FIG. 7C shows surface morphology of the electrodes after the pulse drives. The green luminescence from atomic Ag (at 521 nm and 547 nm as confirmed by spectrum measurement) is distinctly stronger in the Pt-covered Ag area (the overlapping area in the middle) compared to that in the Ag-only area (the right hand side). This indicates that atomization of the Ag electrode occurred more effectively in the Pt-covered area. This is ascribed to the fact that covering the Ag electrode with a thin Pt layer reduces the surface potential barrier for electrons since Pt offers larger work function (6.4 eV) than Ag (4.7 eV), therefore the effective lifetime of Ag ions being created by electron impact ionization is expected to increase because of poor confinement of injected electrons in the Ag layer. The longer lifetime of Ag ions will then reduce the threshold level of injection current density for Coulomb explosion. Due to a similar reason, the probe-touched region in the Pt electrode area also shows locally strong luminescence. The Pt-only area (left), however, did not show any atomic luminescence of Pt, although the area went through an explosive deformation as shown in FIG. 7C. This may be explained by the fact that both the electron impact ionization energy and the binding energy of Pt are significantly higher than Ag, i.e., 9.0 eV versus 7.5 eV for ionization energy and 4.5 eV versus 2.3 eV for binding energy, therefore more difficult to induce Coulomb explosion. From the perspective of thermally induced vaporization, the thermal mass in the double layer (Pt/Ag) region is higher than the single layer (Ag or Pt) region, therefore more difficult to vaporize. However, strongest Ag luminescence was observed from the double layer region, whereas weak Ag atomic luminescence from the Ag-only region and no Pt atomic luminescence from the Pt-only region were detected.

It is believed that an electron beam incident to a thin metal film can induce sputtering of metal atoms. The electron bombardment damage occurs when the incident electrons transfer a sufficient amount of energy to target atoms beyond the level of sputtering threshold (e.g., 7-14 eV for bulk Ag and lower energy for the case of thin films). Because of the large mismatch between electron and atom mass, however, this collision-induced displacement process requires high electron energy (e.g., 100-300 keV electron energy yields only 2-8 eV energy transfer). Considering the upper bound (<100 eV) of electron kinetic energy available under the conditions used in the above non-limiting examples, the possibility of electron-beam induced sputtering of metal is believed to be very low.

Injection of kinetic electrons with high current density may deposit a significant amount of heat into the metal/dielectric system, and may cause melting of metal around the nanochannels. When sufficiently heated, the local metal may vaporize, producing atoms and possibly atomic luminescence. However, when the current density was reduced to the 1/10^{th} level by reducing the pulse voltage from 100 V to 20 V and the total amount of heat deposited during a pulse drive was kept at a constant level by extending the pulse width, explosive deformation of metal (melting/vaporization) did occur while no atomic luminescence was observed during this pulse drive. This result indicates that the thermal melting/vaporization process is unlikely to be the mechanism responsible for atomic luminescence. It is consistent with the Coulomb explosion model which assumes a threshold level of injection current density for explosive atomization.

The time scale of a thermally-induced vaporization (possibly atomization) process estimated from the information on the amount of heat required for vaporization of metal and the pulse drive condition suggests the same time scale (˜1 μs) for Pt and Ag. Both samples showed explosive deformation of metal, but atomic luminescence was observed only from the Ag sample (data not shown). This contrasting result can be explained by the significant difference in their ionization energies (9.0 eV for Pt versus 7.5 eV for Ag). One of the important assumptions of the Coulomb explosion model is that electrons impinging upon metal surface have enough kinetic energy for impact ionization. For the case of electron energy distribution that does not extend well over 10 eV, the ionization yield of Pt may be significantly lower than that of Ag. The result of this second test is also consistent with the Coulomb explosion model.

Compared to the thermal melting/vaporization model, Coulomb explosion is considered to be the dominant mechanism responsible for the observed atomic luminescence. While the overall results are in favor of the Coulomb explosion model over the thermal process as the prime mechanism, possible contributions (an assistive role) by the latter process may not be excluded. The electron-phonon energy relaxation time in metal is known to increase with temperature. It is important to note that an impact process with electrons possessing insufficient energy and/or current density would not induce Coulomb explosion until their energy/current levels rise to a threshold. Those initially unsuccessful bombardments would then result in local heating of metal. The relaxation time (therefore the ion lifetime) is then expected to increase, and this would lower the current density threshold, enhancing the probability of Coulomb explosion. Similarly, the temperature rise would also reduce the cohesive energy of metal, easing the requirement for Coulomb explosion.

This electrically induced explosive atomization offers an interesting potential for chip-scale implementation of elemental analysis of materials placed in contact with the electrode 102 of the device 100 as shown in FIG. 1A.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

What is claimed is:

1. A method of inducing explosive atomization of materials by electrical excitation, comprising:
(A) providing a structure comprising a dielectric layer disposed between a first electrode and a second electrode; and
(B) applying at least one voltage pulse across the first electrode and the second electrode so as to cause Coulomb fragmentation of atoms of at least the first electrode, wherein the Coulomb fragmentation constitutes a microplasma that is substantially localized within the structure.

2. The method of claim 1, wherein the structure comprises a sensor device or a display device.

3. The method of claim 2, wherein:
the structure comprises a sensor device having an analyte located within or adjacent to the first electrode such that the analyte is at least partially ionized by the microplasma;
the method further comprises measuring an electroluminescence of the analyte; and
the analyte is an inorganic or an organic material.

4. The method of claims 3, wherein, prior to the step of applying the at least one voltage pulse, the analyte is deposited by sputtering, spin coating, drop coating, spray coating, or a combination thereof.

5. The method of claim 1, wherein the first electrode comprises a metal and wherein the dielectric layer comprises a solid thin film.

6. The method of claim 5, wherein the metal comprises at least one of Al, Ta, Cr, Mo, W, Ni, Pd, Pt, Cu, Ag, Au, Zn, or Cd, and wherein the dielectric layer has a dielectric constant of about 3 to about 8.

7. The method of claim 6, wherein the metal comprises Ag, and wherein the dielectric layer comprises an oxide of silicon having a thickness less than about 10 nm.

8. The method of claim 1, wherein the first electrode further comprises a Pt layer located on a top surface of the first electrode opposite the dielectric layer.

9. The method of claim 1, the structure further comprises a silicon nitride layer located between the dielectric layer and the first electrode.

10. The method of claim 1, wherein the structure further comprises a semiconductor layer between the dielectric layer and the second electrode.

11. The method of claim 10, wherein the semiconductor layer comprises n-type or p-type doped silicon.

12. The method of claim 11, wherein the semiconductor layer comprises p-type doped silicon.

13. The method of claim 1, wherein the at least one voltage pulse comprises a pulse width between about 1 μs to about 100 ms and a voltage between about −50 V to about −200 V or between about +50 V to about +200 V.

14. A sensor for detecting an analyte via explosive atomization of materials, comprising:
a structure comprising a dielectric layer disposed between a first electrode and a second electrode, wherein the dielectric layer comprises a solid having a thickness less than about 10 nm;
an analyte located within or adjacent to the first electrode such that the analyte is capable of being at least partially atomized or ionized by explosive fragmentation of the first electrode;
a voltage source for providing at least one voltage pulse across the first electrode and the second electrode in order to cause Coulomb fragmentation of atoms of at least the first electrode, wherein the Coulomb fragmentation constitutes a microplasma that is substantially localized within the structure; and
a detector for detecting photons, electrons or ions emitted from the analyte.

15. The sensor of claim 14, wherein the analyte is located on a surface of the first electrode opposite the dielectric layer.

16. The sensor of claim 14, wherein the first electrode comprises a metal and the dielectric comprises an oxide.

17. The sensor of claim 16, wherein the metal comprises at least one of Al, Ta, Cr, Mo, W, Ni, Pd, Pt, Cu, Ag, Au, Zn, or Cd, and the oxide comprises an oxide of silicon.

18. The sensor of claim 14, wherein the structure further comprises a silicon nitride layer located between the dielectric layer and the first electrode.

19. The sensor of claim 14, wherein the first electrode further comprises a Pt layer located on a surface of the first electrode opposite the dielectric layer.

20. A device, comprising:
a first electrode comprising at least a first layer of metal having a low impact ionization energy, wherein the metal is selected from a group consisting of Ag, In, Sn, Zn, Ga, Cu, and a combination thereof, and wherein the first layer is about 5 to 50 nm in thickness;
a second electrode; and
a dielectric layer disposed between a first electrode and a second electrode, the dielectric layer having a thickness less than about 10 nm.

21. The device of claim 20, wherein the first layer is a Ag layer and said thickness is about 10 to 30 nm.

22. The device of claim 20, wherein the first layer is a Ag layer and said thickness is about 10 to 15 nm.

23. The device of claim 20, wherein the first electrode further comprises a Pt layer located over the first layer, and wherein a total thickness of the Pt layer and the first layer is about 5 to 50 nm.

24. The device of claim 20, wherein:
the second electrode comprises a metal selected from Al, Ta, Cr, Mo, W, Ni, Pd, Pt, Cu, Ag, Au, Zn, Cd and a combination thereof,
the dielectric comprises an oxide, and
the sensor further comprises a semiconductor layer between the dielectric layer and the second electrode.

25. The device of claim 20, further comprising:
a voltage source for providing at least one voltage pulse across the first electrode and the second electrode in order to cause Coulomb fragmentation of atoms of at least the first electrode, wherein the Coulomb fragmentation constitutes a microplasma that is substantially localized; and
a detector for detecting photons, electrons or ions emitted from an analyte atomized by the microplasma.
